(19) United States
(12) Patent Application Publication
(10) Pub. No.: US 2006/0159952 A1
(43) Pub. Date: Jul. 20, 2006

(54) Mixed anthracene derivative host materials

(75) Inventors: Michele L. Ricks, Rochester, NY (US); Lelia Cosimbescu, Rochester, NY (US)

Correspondence Address: Pamela R. Crocker;Patent Legal Staff, Eastman Kodak Company, 343 State Street, Rochester, NY, 14650-2201, US

(73) Assignee: Eastman Kodak Company, Rochester, NY (US)

(21) Appl. No.: 11/036,558

(22) Filed: Jan. 14, 2005

(51) Int. Cl. H01L 51/54; H05B 33/14

(52) U.S. Cl. 428/690; 428/917; 313/504; 313/506; 257/103; 257/E51.049

(57) ABSTRACT

An OLED device having at least one light-emitting layer including at least first and second different host materials, wherein the first host material includes an anthracene derivative that can crystallize and the second host material includes a second anthracene derivative which does not crystallize, wherein the stability of the first host material is greater than the stability of the second host material, and the mixed first and second host materials reduce the crystallization effects of the first host material, and the stability of the mixed first and second host materials is improved relative to the stability of the second host material, and a light-emitting material.

### CROSS REFERENCE TO RELATED APPLICATIONS

Reference is made to commonly assigned U.S. patent application Ser. No. 10/780,436 filed Feb. 17, 2004 by Michele L. Ricks, et al., entitled “Anthracene Derivative Host Having Ranges of Dopants”, commonly assigned U.S. patent application Ser. No. 10/950,614 filed Sep. 27, 2004 by Lelia Cosimbescu, et al., entitled “Electroluminescent Device With Anthracene Derivative Host”, and commonly assigned U.S. patent application Ser. No. 10/819,697 filed Apr. 7, 2004 by Michael L. Boroson, et al., entitled “Color OLED With Added Color Gamut Pixels”, the disclosures of which are herein incorporated by reference.

### FIELD OF THE INVENTION

The present invention relates to improved host materials for OLED displays.

### BACKGROUND OF THE INVENTION

An organic light-emitting diode device, also called an OLED device, commonly includes a substrate, an anode, a hole-transporting layer made of an organic compound, an organic luminescent layer with suitable dopants, an organic electron-transporting layer, and a cathode. OLED devices are attractive because of their low driving voltage, high luminance, wide-angle viewing and capability for full color flat emission displays. Tang, et al. described this multilayer OLED device in their U.S. Pat. Nos. 4,769,292 and 4,885,211.

A white-emitting electroluminescent (EL) layer can be used to form a multicolor device. Each pixel is coupled with a color filter element as part of a color filter array (CFA) to achieve a pixilated multicolor display. The organic EL layer is common to all pixels and the final color as perceived by the viewer is dictated by that pixel's corresponding color filter element. Therefore a multicolor or RGB device can be produced without requiring any patterning of the organic EL layers. An example of a white CFA top-emitting device is shown in U.S. Pat. No. 6,392,340.

White light producing OLED devices should be bright, efficient, and generally have Commission International d'Eclairage (CIE) chromaticity coordinates of about (0.33, 0.33). In any event, in accordance with this disclosure, white light is that light which is perceived by a user as having a white color. The following patents and publications disclose the preparation of organic OLED devices capable of producing white light, comprising a hole-transporting layer and an organic luminescent layer, and interposed between a pair of electrodes.

White light producing OLED devices have been reported before by J. Shi (U.S. Pat. No. 5,683,823) wherein the luminescent layer includes red and blue light-emitting materials uniformly dispersed in a host emitting material. Sato, et al. in JP 07-142169 disclose an OLED device, capable of emitting white light, made by forming a blue light-emitting layer next to the hole-transporting layer and followed by a green light-emitting layer having a region containing a red fluorescent layer.

Kido, et al., in Science, 267, 1332 (1995) and in Applied Physics Letters, 64, 815 (1994), report a white light-producing OLED device. In this device, three emitter layers with different carrier transport properties, each emitting blue, green, or red light, are used to produce white light. Littman, et al. in U.S. Pat. No. 5,405,709 disclose another white emitting device, which is capable of emitting white light in response to hole-electron recombination, and includes a fluorescent in a visible light range from bluish green to red. More recently, Deshpande, et al., in Applied Physics Letters, 75, 888 (1999), published a white OLED device using red, blue, and green luminescent layers separated by a hole-blocking layer.

Anthracene based hosts are often used. A useful class of 9,10-di-(2-naphthyl)anthracene hosts has been disclosed in U.S. Pat. No. 5,935,721. Bis-anthracene compounds used in the luminescent layer with an improved device half-life have been disclosed in U.S. Pat. No. 6,534,199 and U.S. Patent Application Publication 2002/136,922 A1. Electroluminescent devices with improved luminance using anthracene compounds have been disclosed in U.S. Pat. No. 6,582,837. Ikeda, et al., in WO 2004/108587, disclose the use of anthracenes in which one substituent is an aromatic system comprising two or more rings, e.g. a naphthyl group, and a second substituent is a monocyclic aromatic ring substituted with additional aromatic groups, e.g. a biphenyl group. Anthracenes have also been used in the hole-transporting layer (HTL) as disclosed in U.S. Pat. No. 6,465,115. Hatwar, et al., in U.S. Patent Application Publication 2003/0071565 A1, disclose the use of ADN and TBADN in a hole-transporting layer as a color-neutral dopant. In addition there are other disclosures of using anthracene materials in OLED devices, U.S. Pat. No. 5,972,247, JP 2001-097897, JP 2000-273056, JP 2000-053677, JP 2001-335516, WO 03/060,956, WO 02/088,274, and WO 03/007,658.

Despite these advances, there is a continuing need for hosts and dopants that provide better operational stability and are conveniently made. Improved operational stability of OLED devices will permit their use in more products.

### SUMMARY OF THE INVENTION

It is therefore an object of the present invention to provide an organic light-emitting layer with effective stability that does not crystallize, while using host material that provides effective stability but has a tendency to crystallize under some processing conditions.

This object is achieved in an OLED device having at least one light-emitting layer, the improvement comprising:

a) at least first and second different host materials, wherein the first host material includes an anthracene derivative that can crystallize and the second host material includes a second anthracene derivative which does not crystallize, wherein the stability of the first host material is greater than the stability of the second host material, and the mixed first and second host materials reduce the crystallization effects of the first host material, and the stability of the mixed first and second host materials is improved relative to the stability of the second host material; and

b) a light-emitting material.

### ADVANTAGES

It is an advantage of the present invention that a white light-emitting OLED device can be prepared with effective stability without the formation of crystals in the host. It is a further advantage that this invention can be used with some emitters to provide adjustments to the hue.

### BRIEF DESCRIPTION OF THE DRAWINGS

FIG. 1 is a cross-sectional view of a single light-emitting pixel of an OLED display according to this invention.

Since device feature dimensions such as layer thicknesses are frequently in sub-micrometer ranges, the drawings are scaled for ease of visualization rather than dimensional accuracy.

### DETAILED DESCRIPTION OF THE INVENTION

The term “OLED device” or “organic light-emitting display” is used in its art recognized meaning of a display device comprising organic light-emitting diodes as pixels. A color OLED device emits light of at least one color. The term “multicolor” is employed to describe a display panel that is capable of emitting light of a different hue in different areas. In particular, it is employed to describe a display panel that is capable of displaying images of different colors. These areas are not necessarily contiguous. The term “full color” is commonly employed to describe multicolor display panels that are capable of emitting in the red, green, and blue regions of the visible spectrum and displaying images in any combination of hues. The red, green, and blue colors constitute the three primary colors from which all other colors can be produced by appropriate mixing. The term “hue” refers to the intensity profile of light emission within the visible spectrum, with different hues exhibiting visually discernible differences in color. The term “pixel” is employed, in its art recognized usage, to designate an area of a display panel that can be stimulated to emit light independently of other areas. It is recognized that in full color systems, several pixels of different colors will be used together to produce a wide range of colors, and a viewer can term such a group a single pixel. For the purposes of this discussion, such a group will be considered several different colored pixels.

In accordance with this disclosure, broadband emission is light that has significant components in multiple portions of the visible spectrum, for example, blue and green. Broadband emission can also include the situation where light is emitted in the red, green, and blue portions of the spectrum in order to produce white light. White light is that light that is perceived by a user as having a white color, or light that has an emission spectrum sufficient to be used in combination with color filters to produce a multicolor or full color display. Although CIEx, CIEy coordinates of about 0.33, 0.33 can be ideal in some circumstances, the actual coordinates can vary significantly and still be very useful.

The present invention can be employed in most OLED device configurations. These include very simple structures comprising a single anode and cathode to more complex devices, including passive matrix displays including orthogonal arrays of anodes and cathodes to form pixels, and active-matrix displays where each pixel is controlled independently, for example, with thin film transistors (TFTs). OLED devices of this invention can operate under forward biasing and so can function under DC mode. It is sometimes advantageous to apply a reverse bias, e.g. in an alternating mode. The OLED typically does not emit light under reverse bias, but significant stability enhancements have been demonstrated, as described in U.S. Pat. No. 5,552,678.

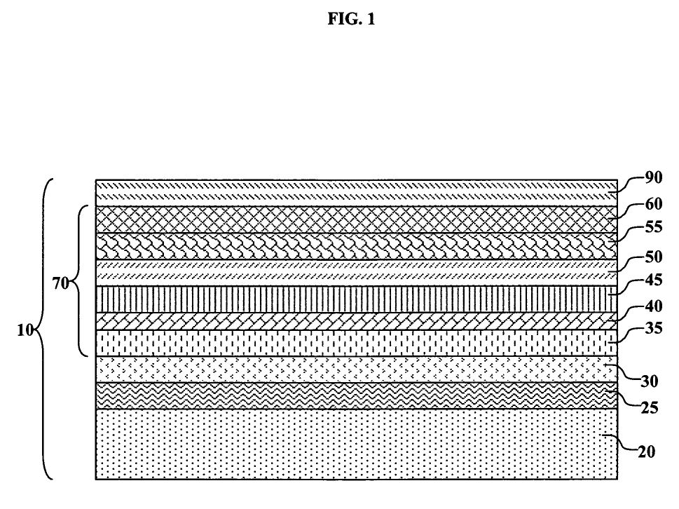

Turning now to FIG. 1, there is shown a cross-sectional view of a pixel of a white light-emitting OLED device 10 that can be used according to a first embodiment of the present invention. Such an OLED device can be incorporated into e.g. a display or an area lighting system. The OLED device 10 includes at a minimum a substrate 20, an anode 30, a cathode 90 spaced from anode 30, and a light-emitting layer 45, which is a blue-light-emitting layer. It has been found in commonly assigned U.S. patent application Ser. No. 10/950,614filed Sep. 27, 2004 by Lelia Cosimbescu, et al., entitled “Electroluminescent Device With Anthracene Derivative Host”, the disclosure of which is herein incorporated by reference, that certain asymmetric anthracene derivatives are extremely useful in OLED devices that exhibit high efficiencies, due to their operational stability. These compounds have been found to be particularly useful in blue-light-emitting layers of OLED devices, e.g. those that produce white light. Light-emitting layer 45 includes a monoanthracene derivative of Formula (I) as a first host material: 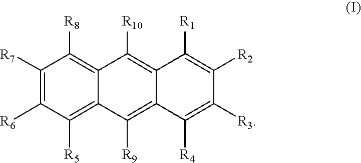
In Formula (I), R₁-R₈ are H.

R₉ is a naphthyl group containing no fused rings with aliphatic carbon ring members; provided that R₉ and R₁₀ are not the same, and are free of amines and sulfur compounds. Suitably, R₉ is a substituted naphthyl group with one or more further fused rings such that it forms a fused aromatic ring system, such as a phenanthryl, pyrenyl, fluoranthene, perylene, or substituted with one or more substituents such as fluorine, cyano group, hydroxy, alkyl, alkoxy, aryloxy, aryl, a heterocyclic oxy group, carboxy, trimethylsilyl group, or an unsubstituted naphthyl group of two fused rings. Conveniently, R₉ is 2-naphthyl, or 1-naphthyl substituted or unsubstituted in the para position.

R₁₀ is a biphenyl group having no fused rings with aliphatic carbon ring members. Suitably R₁₀ is a substituted biphenyl group, such that is forms a fused aromatic ring system including but not limited to a naphthyl, phenanthryl, perylene, or substituted with one or more substituents such as fluorine, cyano group, hydroxy, alkyl, alkoxy, aryloxy, aryl, a heterocyclic oxy group, carboxy, trimethylsilyl group, or an unsubstituted biphenyl group. Conveniently, R₁₀ is 4-biphenyl, 3-biphenyl unsubstituted or substituted with another phenyl ring without fused rings to form a terphenyl ring system, or 2-biphenyl.

Useful first host materials of this invention include:

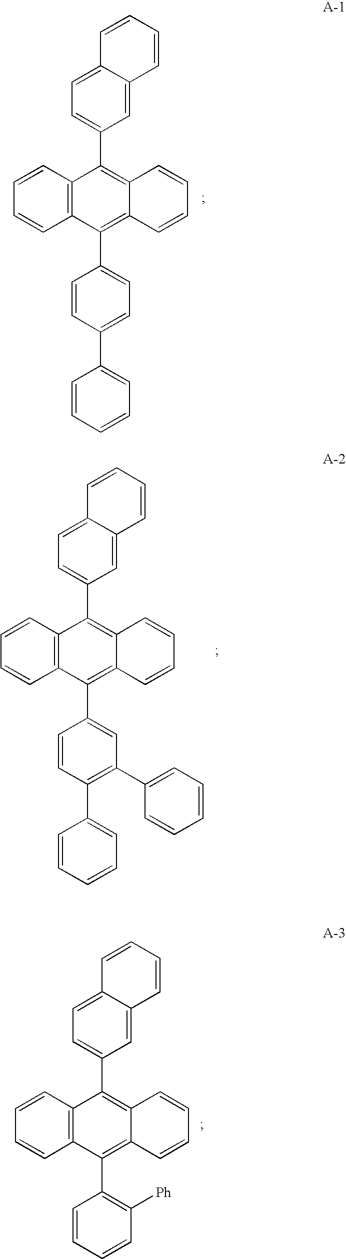

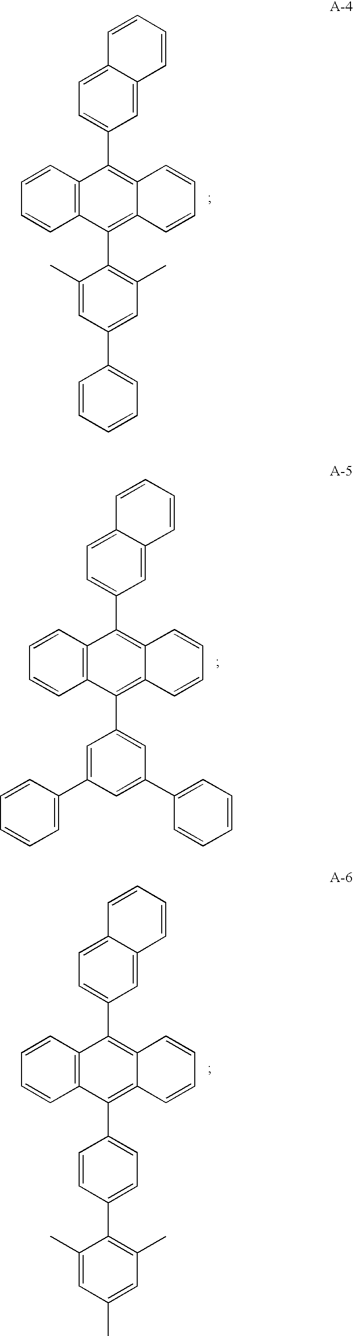

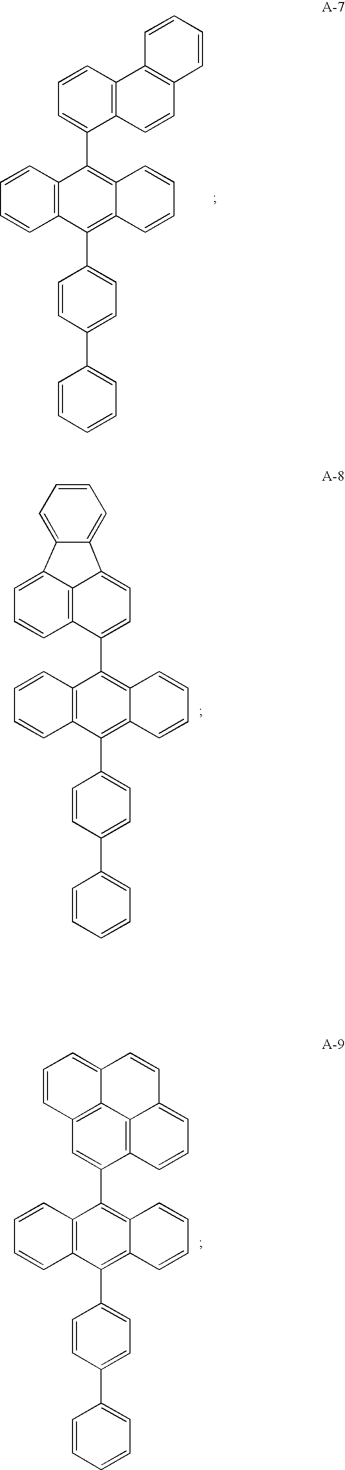

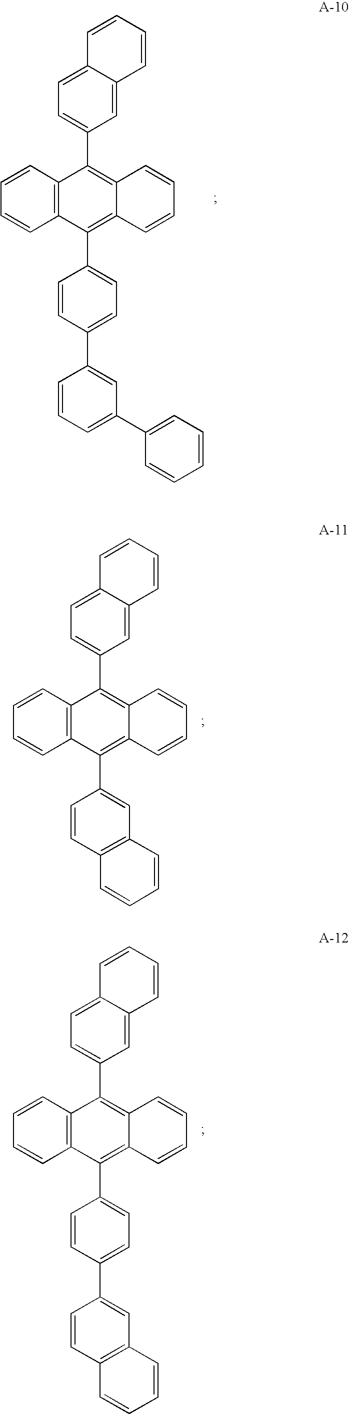

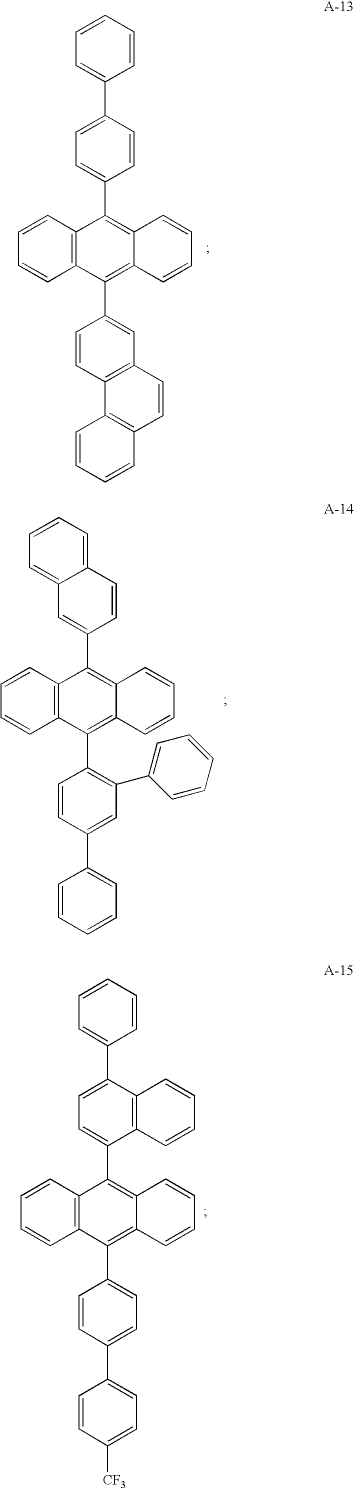

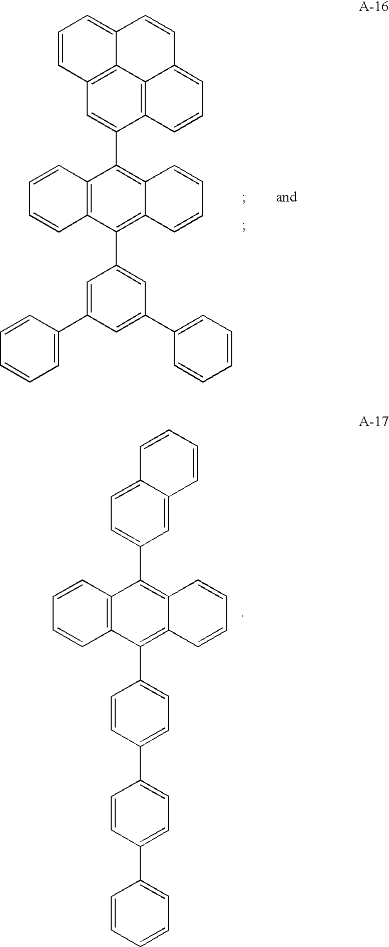

Particularly useful is 9-(2-naphthyl)- 10-(4-biphenyl)anthracene (A-1). A-1 can provide a light-emitting layer having effective lifetime and efficiency. However, it has been found that layers that use A-I as the only host material can crystallize under certain conditions. Areas that crystallize will not emit light or they can be dim relative to areas that are not crystallized.

An improvement has been found whereby crystallization of the host can be limited while retaining much of the stability by including a second host material that includes a second anthracene derivative that does not crystallize. By second anthracene derivative, it is meant a second compound that includes an anthracene group and is different from the anthracene derivative of the first host material. The second anthracene derivative is selected so that the stability of the first host material is greater than the stability of the second host material. The second host material has the formula:

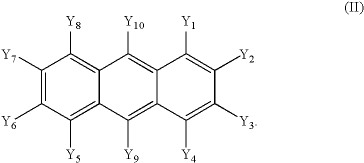

In Formula (II), Y₁-Y₈ are independently H, an alkyl group, an alkoxy group, or an alkenyl group, and at least one of Y₁-Y₈ is not H. Y₉ and Y₁₀ are aromatic groups and Y₉ is the same as Y₁₀. Conveniently, Y₉ and Y₁₀ include but are not limited to phenyl, tolyl, biphenyl, naphthyl, terphenyl, fluoranthenyl, fluorenyl, pyrenyl, or phenanthryl, as well as a heteroaromatic ring such as pyridinyl or quinolinyl. Suitably, Y₉ and Y₁₀ are 2-naphthyl, tolyl, biphenyl. Useful second host materials include:

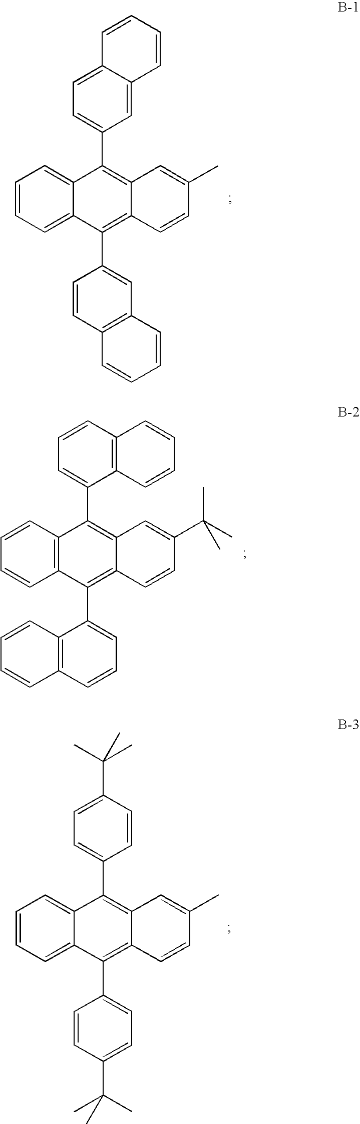

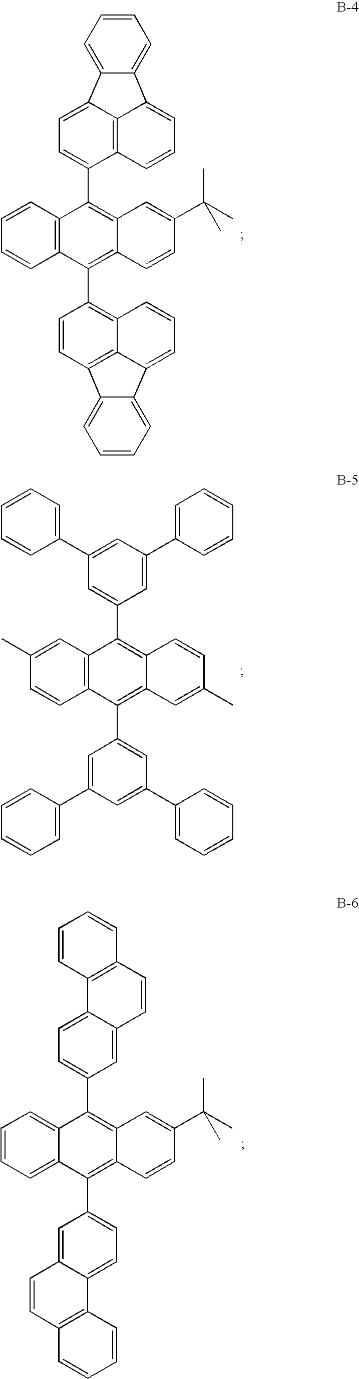

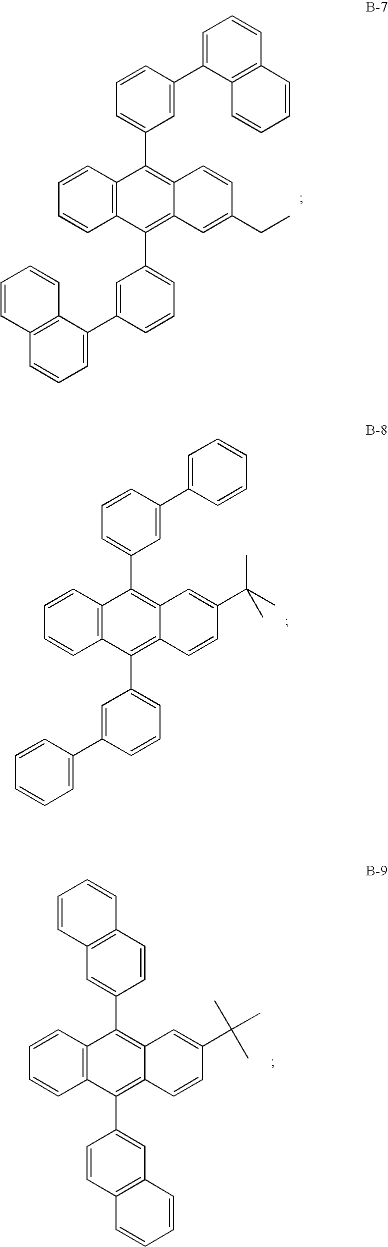

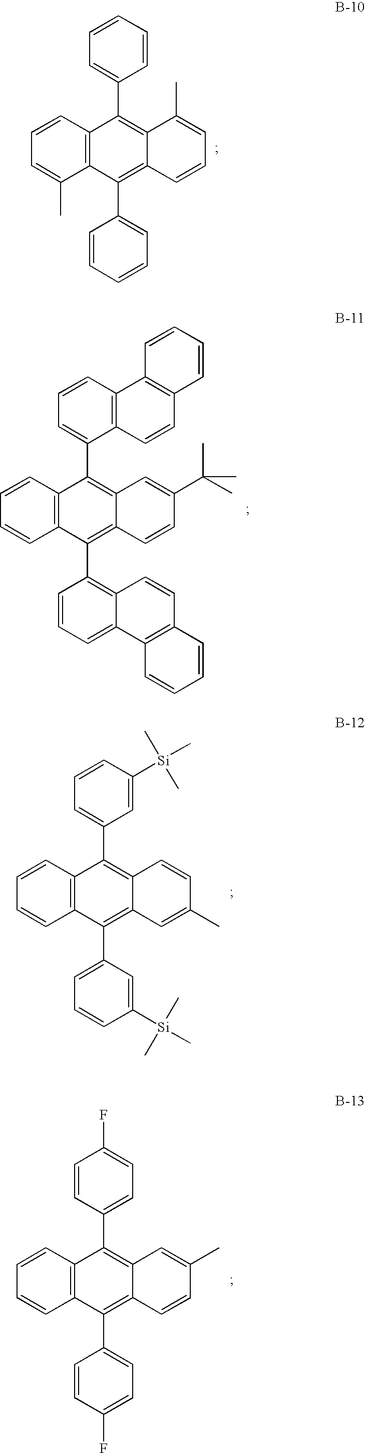

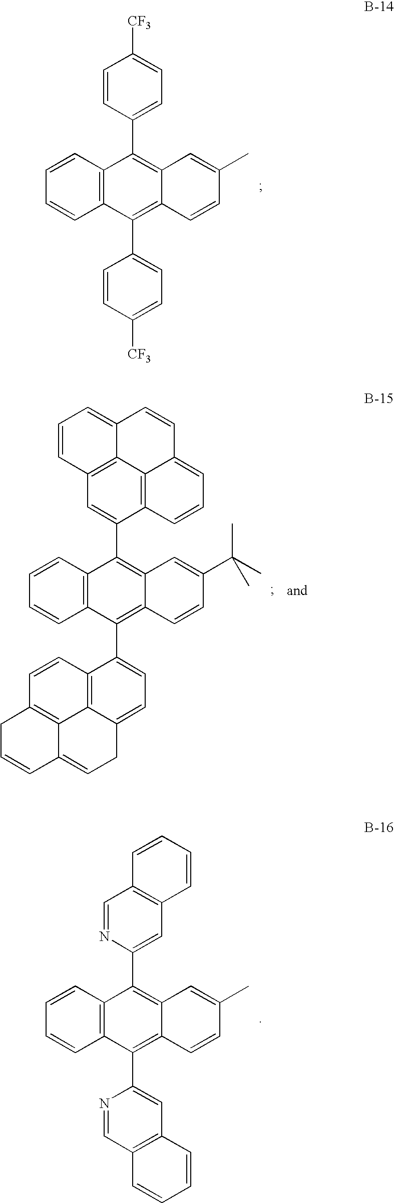

Derivatives of 9,10-bis(2-naphthyl)anthracene (Formula III) constitute one class of useful second host materials capable of supporting electroluminescence 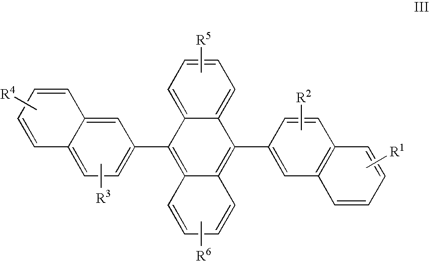
wherein R¹, R², R³, R⁴, R⁵, and R⁶ represent one or more substituents on each ring where each substituent is individually selected from the following groups:

Group 1: hydrogen, or alkyl of from 1 to 24 carbon atoms;

Group 2: aryl or substituted aryl of from 5 to 20 carbon atoms;

Group 3: carbon atoms from 4 to 24 necessary to complete a fused aromatic ring of anthracenyl, pyrenyl, or perylenyl;

Group 4: heteroaryl or substituted heteroaryl of from 5 to 24 carbon atoms as necessary to complete a fused heteroaromatic ring of furyl, thienyl, pyridyl, quinolinyl or other heterocyclic systems;

Group 5: alkoxylamino, alkylamino, or arylamino of from 1 to 24 carbon atoms; and

Group 6: fluorine, or cyano.

Particularly useful is 2-tert-butyl-9,10-bis(2-naphthyl)-anthracene (TBADN, compound B-9).

Host materials of the invention are employed in light-emitting layer 45 comprising a certain thickness, together with a dopant or light-emitting material as defined below. The first host material is in the range of from 10-90 percent by volume of the mixture of the first and second host materials. The mixed first and second host materials reduce the crystallization effects of the first host material, and the stability of the mixed first and second host materials is improved relative to the stability of the second host material.

It is an advantage of the hosts of the invention that they are free of sulfur and amines. The process of preparing the materials as well as their purification is simple and efficient and environmentally friendly, thus making these compounds conveniently manufacturable.

Unless otherwise specifically stated, use of the term “substituted” or “substituent” means any group or atom other than hydrogen. Additionally, when the term “group” is used, it means that when a substituent group contains a substitutable hydrogen, it is also intended to encompass not only the substituent's unsubstituted form, but also its form further substituted with any substituent group or groups as herein mentioned, so long as the substituent does not destroy properties necessary for device utility. Suitably, a substituent group may be halogen or may be bonded to the remainder of the molecule by an atom of carbon, silicon, oxygen, nitrogen, phosphorous, selenium, or boron. The substituent may be, for example, halogen, such as fluoro; silicon; nitro; hydroxyl; cyano; carboxyl; or groups which may be further substituted, such as alkyl, including straight or branched chain or cyclic alkyl, such as methyl, trifluoromethyl, ethyl, t-butyl; alkenyl, such as ethylene, 2-butene; alkoxy, such as methoxy, ethoxy, propoxy, butoxy, 2-methoxyethoxy, sec-butoxy; aryl such as phenyl, 4-t-butylphenyl, 2,4,6-trimethylphenyl, naphthyl, biphenyl; aryloxy, such as phenoxy, 2-methylphenoxy, alpha- or beta-naphthyloxy, and 4-tolyloxy; amine, phosphate, phosphite, a heterocyclic group, a heterocyclic oxy group or a heterocyclic thio group, each of which may be substituted and which contain a 3 to 7 membered heterocyclic ring composed of carbon atoms and at least one hetero atom selected from the group consisting of oxygen, nitrogen, sulfur, phosphorous, or boron, quaternary phosphonium, such as triphenylphosphonium; and silyloxy, such as trimethylsilyloxy.

If desired, the substituents may themselves be further substituted one or more times with the described substituent groups. The particular substituents used may be selected by those skilled in the art to attain the desired desirable properties for a specific application and can include, for example, electron-withdrawing groups, electron-donating groups, and steric groups. When a molecule may have two or more substituents, the substituents may be joined together to form a ring such as a fused ring unless otherwise provided. Generally, the above groups and substituents thereof may include those having up to 48 carbon atoms, typically 1 to 36 carbon atoms and usually less than 24 carbon atoms, but greater numbers are possible depending on the particular substituents selected.

The light-emitting material in light-emitting layer 45 is from 0.25 to 5% by volume of the host material and can include perylene or derivatives thereof, blue-emitting derivatives of distyrylbenzene or a distyrylbiphenyl, or a bis(azinyl)azine boron complex compound of the structure 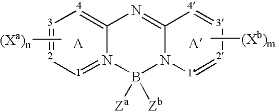
wherein:

A and A′ represent independent azine ring systems corresponding to 6-membered aromatic ring systems containing at least one nitrogen;

(X^{a})ₙ and (X^{b})ₘ represent one or more independently selected substituents and include acyclic substituents or are joined to form a ring fused to A or A′;

m and n are independently 0 to 4;

Z^{a} and Z^{b} are independently selected substituents;

1, 2, 3, 4, 1′, 2′, 3′, and 4′ are independently selected as either carbon or nitrogen atoms; and

provided that X^{a}, X^{b}, Z^{a}, and Z^{b}, 1, 2, 3, 4, 1′, 2′, 3′, and 4′ are selected to provide blue luminescence, which is defined as an emission maximum between 440 and 490 nm.

Some examples of the above class of dopants include the following:

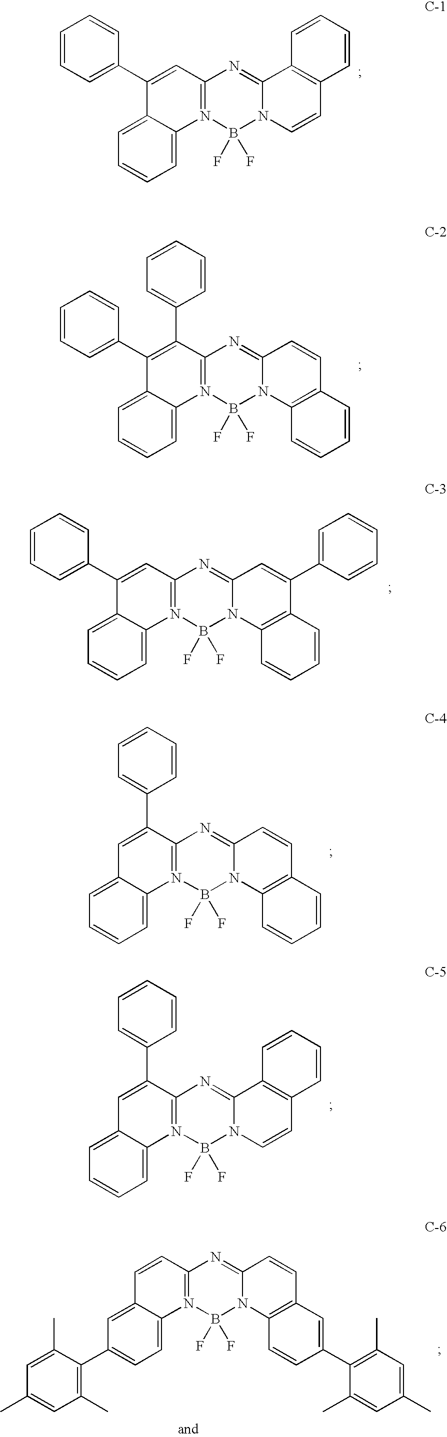

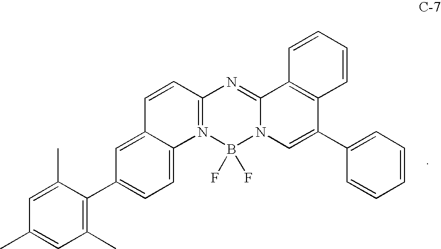

Another particularly useful class of blue dopants in this invention includes blue-emitting derivatives of such distyrylarenes as distyrylbenzene and distyrylbiphenyl, including compounds described in U.S. Pat. No. 5,121,029. Among derivatives of distyrylarenes that provide blue luminescence, particularly useful are those substituted with diarylamino groups, also known as distyrylamines. Examples include bis[2-[4-[N,N-diarylamino]phenyl]vinyl]-benzenes of the general structure N1 shown below: 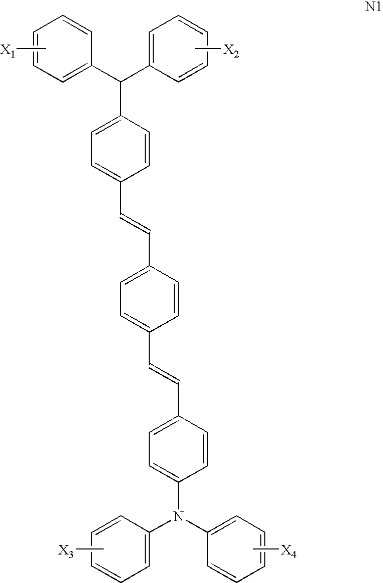
and bis[2-[4-[N,N-diarylamino]phenyl]vinyl]biphenyls of the general structure N2 shown below:

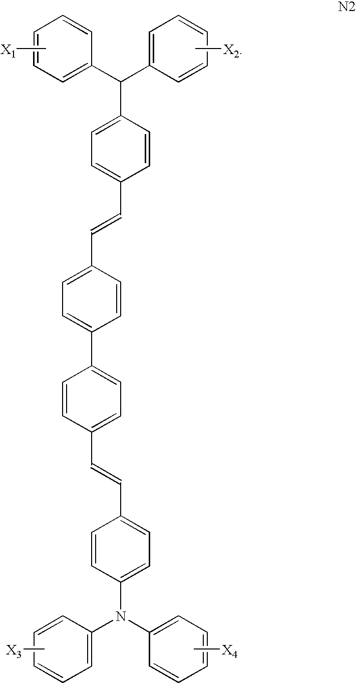

In Formulas N1 and N2, X₁-X₄ can be the same or different, and individually represent one or more substituents such as alkyl, aryl, fused aryl, halo, or cyano. In a preferred embodiment, X₁-X₄ are individually alkyl groups, each containing from one to about ten carbon atoms. A particularly preferred blue dopant of this class is 1,4-bis[2-[4-[N,N-di(p-tolyl)amino]phenyl]vinyl]benzene

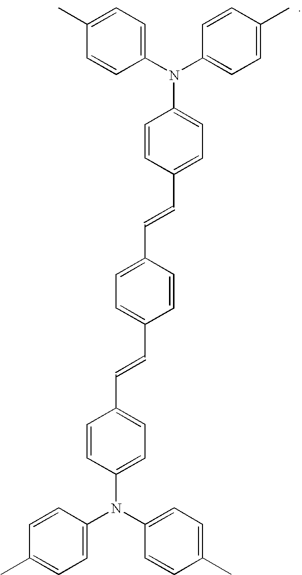

Particularly useful blue dopants of the perylene class include perylene (L1) and tetra-t-butylperylene (L2)

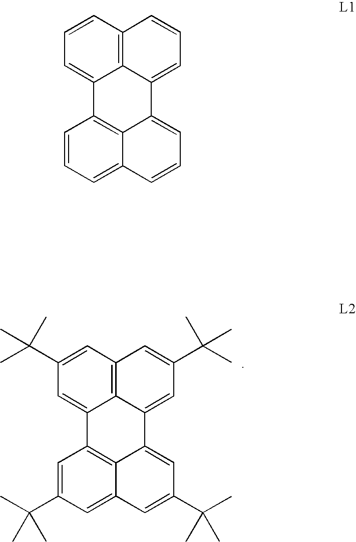

Substrate 20 can be an organic solid, an inorganic solid, or include organic and inorganic solids. Substrate 20 can be rigid or flexible and can be processed as separate individual pieces, such as sheets or wafers, or as a continuous roll. Typical substrate materials include glass, plastic, metal, ceramic, semiconductor, metal oxide, semiconductor oxide, or semiconductor nitride, or combinations thereof Substrate 20 can be a homogeneous mixture of materials, a composite of materials, or multiple layers of materials. Substrate 20 can be an OLED substrate, that is a substrate commonly used for preparing OLED devices, e.g. active-matrix low-temperature polysilicon or amorphous-silicon TFT substrate. The substrate 20 can either be light transmissive or opaque, depending on the intended direction of light emission. The light transmissive property is desirable for viewing the EL emission through the substrate. Transparent glass or plastic are commonly employed in such cases. For applications where the EL emission is viewed through the top electrode, the transmissive characteristic of the bottom support is immaterial, and therefore can be light transmissive, light absorbing, or light reflective. Substrates for use in this case include, but are not limited to, glass, plastic, semiconductor materials, ceramics, and circuit board materials, or any others commonly used in the formation of OLED devices, which can be either passive-matrix devices or active-matrix devices.

An electrode is formed over substrate 20 and is most commonly configured as an anode 30. When EL emission is viewed through the substrate 20, anode 30 should be transparent or substantially transparent to the emission of interest. Common transparent anode materials useful in this invention are indium-tin oxide and tin oxide, but other metal oxides can work including, but not limited to, aluminum- or indium-doped zinc oxide, magnesium-indium oxide, and nickel-tungsten oxide. In addition to these oxides, metal nitrides such as gallium nitride, metal selenides such as zinc selenide, and metal sulfides such as zinc sulfide, can be used as an anode material. For applications where EL emission is viewed through the top electrode, the transmissive characteristics of the anode material are immaterial and any conductive material can be used, transparent, opaque or reflective. Example conductors for this application include, but are not limited to, gold, iridium, molybdenum, palladium, and platinum. The preferred anode materials, transmissive or otherwise, have a work function of 4.1 eV or greater. Desired anode materials can be deposited by any suitable way such as evaporation, sputtering, chemical vapor deposition, or electrochemical means. Anode materials can be patterned using well known photolithographic processes.

Cathode 90 is formed over light-emitting layer 45. When light emission is through the anode 30, the cathode material can include nearly any conductive material. Desirable materials have effective film-forming properties to ensure effective contact with the underlying organic layer, promote electron injection at low voltage, and have effective stability. Useful cathode materials often contain a low work function metal (<3.0 eV) or metal alloy. One preferred cathode material includes a Mg:Ag alloy wherein the percentage of silver is in the range of 1 to 20%, as described in U.S. Pat. No. 4,885,221. Another suitable class of cathode materials includes bilayers including a thin layer of a low work function metal or metal salt capped with a thicker layer of conductive metal. One such cathode includes a thin layer of LiF followed by a thicker layer of A1 as described in U.S. Pat. No. 5,677,572. Other useful cathode materials include, but are not limited to, those disclosed in U.S. Pat. Nos. 5,059,861, 5,059,862, and 6,140,763.

When light emission is viewed through cathode 90, it should be transparent or nearly transparent. For such applications, metals should be thin or one should use transparent conductive oxides, or include these materials. Optically transparent cathodes have been described in more detail in U.S. Pat. No. 5,776,623. Cathode materials can be deposited by evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

Cathode 90 is spaced, by which it is meant it is vertically spaced apart from anode 30. Cathode 90 can be part of an active matrix device and, in that case, is a single electrode for the entire display. Alternatively, cathode 90 can be part of a passive matrix device, in which each cathode 90 can activate a column of pixels, and cathodes 90 are arranged orthogonal to anodes 30.

OLED device 10 can also include color filter 25, a hole-injecting layer 35, a hole-transporting layer 40, a second light-emitting layer 50, an electron-transporting layer 55, and an electron-injecting layer 60. Hole-injecting layer 35, hole-transporting layer 40, light-emitting layers 45 and 50, electron-transporting layer 55, and electron-injecting layer 60 include organic EL element 70 that is disposed between anode 30 and cathode 90 and that, for the purposes of this invention, includes at least two different dopants for collectively emitting white light. These components will be described in more detail.

While not always necessary, it is often useful that a hole-injecting layer 35 be formed over anode 30 in an organic light-emitting display. The hole-injecting material can serve to improve the film formation property of subsequent organic layers and to facilitate injection of holes into the hole-transporting layer. Suitable materials for use in hole-injecting layer 35 include, but are not limited to, porphyrinic compounds as described in U.S. Pat. No. 4,720,432, plasma-deposited fluorocarbon polymers as described in U.S. Pat. No. 6,208,075, and inorganic oxides including vanadium oxide (VOx), molybdenum oxide (MoOx), and nickel oxide (NiOx). Alternative hole-injecting materials reportedly useful in organic EL devices are described in EP 0 891 121 A1 and EP 1 029 909 A1.

While not always necessary, it is often useful that a hole-transporting layer 40 be formed and disposed over anode 30. Desired hole-transporting materials can be deposited by any suitable way such as evaporation, sputtering, chemical vapor deposition, electrochemical means, thermal transfer, or laser thermal transfer from a donor material. Hole-transporting materials useful in hole-transporting layer 40 are well known to include compounds such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel, et al. in U.S. Pat. No. 3,180,730. Other suitable triarylamines substituted with one or more vinyl radicals and/or comprising at least one active hydrogen-containing group are disclosed by Brantley, et al. in U.S. Pat. Nos. 3,567,450 and 3,658,520.

A more preferred class of aromatic tertiary amines is those which include at least two aromatic tertiary amine moieties as described in U.S. Pat. Nos. 4,720,432 and 5,061,569. Such compounds include those represented by structural Formula A 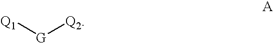
wherein:

Q₁ and Q₂ are independently selected aromatic tertiary amine moieties; and

G is a linking group such as an arylene, cycloalkylene, or alkylene group of a carbon to carbon bond.

In one embodiment, at least one of Q₁ or Q₂ contains a polycyclic fused ring structure, e.g., a naphthalene. When G is an aryl group, it is conveniently a phenylene, biphenylene, or naphthalene moiety.

A useful class of triarylamines satisfying structural Formula A and containing two triarylamine moieties is represented by structural Formula B 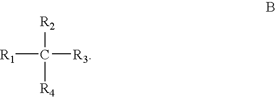
wherein:

R₁ and R₂ each independently represent a hydrogen atom, an aryl group, or an alkyl group or R₁ and R₂ together represent the atoms completing a cycloalkyl group; and

R₃ and R₄ each independently represent an aryl group, which is in turn substituted with a diaryl substituted amino group, as indicated by structural Formula C 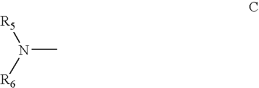
wherein R₅ and R₆ are independently selected aryl groups. In one embodiment, at least one of R₅ or R₆ contains a polycyclic fused ring structure, e.g., a naphthalene.

Another class of aromatic tertiary amines are the tetraaryldiamines. Desirable tetraaryldiamines include two diarylamino groups, such as indicated by Formula C, linked through an arylene group. Useful tetraaryldiamines include those represented by Formula D 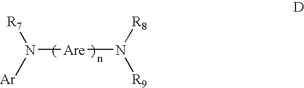
wherein:

each Are is an independently selected arylene group, such as a phenylene or anthracene moiety;

n is an integer of from 1 to 4; and

Ar, R₇, R₈, and R₉ are independently selected aryl groups.

In a typical embodiment, at least one of Ar, R₇, R₈, and R₉ is a polycyclic fused ring structure, e.g., a naphthalene.

The various alkyl, alkylene, aryl, and arylene moieties of the foregoing structural Formulae A, B, C, D, can each in turn be substituted. Typical substituents include alkyl groups, alkoxy groups, aryl groups, aryloxy groups, and halogens such as fluoride, chloride, and bromide. The various alkyl and alkylene moieties typically contain from 1 to about 6 carbon atoms. The cycloalkyl moieties can contain from 3 to about 10 carbon atoms, but typically contain five, six, or seven carbon atoms, e.g. cyclopentyl, cyclohexyl, and cycloheptyl ring structures. The aryl and arylene moieties are typically phenyl and phenylene moieties.

The hole-transporting layer in an OLED device can be formed of a single or a mixture of aromatic tertiary amine compounds. Specifically, one can employ a triarylamine, such as a triarylamine satisfying the Formula B, in combination with a tetraaryldiamine, such as indicated by Formula D. When a triarylamine is employed in combination with a tetraaryldiamine, the latter is positioned as a layer interposed between the triarylamine and the electron-injecting and transporting layer. Illustrative of useful aromatic tertiary amines are the following:

1,1-Bis(4-di-p-tolylaminophenyl)cyclohexane;

1,1-Bis(4-di-p-tolylaminophenyl)-4-phenylcyclohexane;

4,4′-Bis(diphenylamino)quadriphenyl;

Bis(4-dimethylamino-2-methylphenyl)-phenylmethane;

N,N,N-Tri(p-tolyl)amine;

4-(di-p-tolylamino)-4′-[4(di-p-tolylamino)-styryl]stilbene;

N,N,N′,N′-Tetra-p-tolyl-4-4′-diaminobiphenyl;

N,N,N′,N′-Tetraphenyl-4,4′-diaminobiphenyl;

N-Phenylcarbazole;

Poly(N-vinylcarbazole);

N,N′-di-1-naphthalenyl-N,N′-diphenyl-4,4′-diaminobiphenyl;

4,4′-Bis[N-(1-naphthyl)-N-phenylamino]biphenyl;

4,4″-Bis[N-(1-naphthyl)-N-phenylamino]p-terphenyl;

4,4′-Bis[N-(2-naphthyl)-N-phenylamino]biphenyl;

4,4′-Bis[N-(3-acenaphthenyl)-N-phenylamino]biphenyl;

1,5-Bis[N-(1-naphthyl)-N-phenylamino]naphthalene;

4,4′-Bis[N-(9-anthryl)-N-phenylamino]biphenyl;

4,4″-Bis[N-(1-anthryl)-N-phenylamino]-p-terphenyl;

4,4′-Bis[N-(2-phenanthryl)-N-phenylamino]biphenyl;

4,4′-Bis[N-(8-fluoranthenyl)-N-phenylamino]biphenyl;

4,4′-Bis[N-(2-pyrenyl)-N-phenylamino]biphenyl;

4,4′-Bis[N-(2-naphthacenyl)-N-phenylamino]biphenyl;

4,4′-Bis[N-(2-perylenyl)-N-phenylamino]biphenyl;

4,4′-Bis[N-(1-coronenyl)-N-phenylamino]biphenyl;

2,6-Bis(di-p-tolylamino)naphthalene;

2,6-Bis[di-(1-naphthyl)amino]naphthalene;

2,6-Bis[N-(1-naphthyl)-N-(2-naphthyl)amino]naphthalene;

N,N,N′,N′-Tetra(2-naphthyl)-4,4″-diamino-p-terphenyl;

4,4′-Bis{N-phenyl-N-[4-(1-naphthyl)-phenyl]amino}biphenyl;

4,4′-Bis[N-phenyl-N-(2-pyrenyl)amino]biphenyl;

2,6-Bis[N,N-di(2-naphthyl)amine]fluorene; and

1,5-Bis[N-(1-naphthyl)-N-phenylamino]naphthalene.

Another class of useful hole-transporting materials includes polycyclic aromatic compounds as described in EP 1 009 041. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Optional second light-emitting layer 50 produces light in response to hole-electron recombination. Yellow-, orange-, or red-light-emitting layer 50 is adjacent to blue-light-emitting layer 45 to produce a broadband-emitting device, e.g. a white light-emitting OLED device. Desired organic light-emitting materials can be deposited by any suitable way such as evaporation, sputtering, chemical vapor deposition, electrochemical means, or radiation thermal transfer from a donor material. Useful organic light-emitting materials are well known. As more fully described in U.S. Pat. Nos. 4,769,292 and 5,935,721, the light-emitting layers of the organic EL element includes a luminescent or fluorescent material where electroluminescence is produced as a result of electron-hole pair recombination in this region. Light-emitting layer 50 includes a single material, but more commonly includes a host material doped with a guest compound or dopant where light emission comes primarily from the dopant.

The dopant is selected to produce color light having a particular spectrum in the yellow to red region. The host materials in the light-emitting layers can be an electron-transporting material, as defined below, a hole-transporting material, as defined above, or another material that supports hole-electron recombination. The dopant is typically chosen from highly fluorescent dyes, but phosphorescent compounds, e.g., transition metal complexes as described in WO 98/55561, WO 00/18851, WO 00/57676, and WO 00/70655 are also useful. Dopants are typically coated as 0.1 to 10% by weight into the host material.

An important relationship for choosing a dye as a dopant is a comparison of the bandgap potential which is defined as the energy difference between the highest occupied molecular orbital and the lowest unoccupied molecular orbital of the molecule. For efficient energy transfer from the host material to the dopant molecule, a necessary condition is that the band gap of the dopant is smaller than that of the host material.

Host and emitting molecules known to be of use include, but are not limited to, those disclosed in U.S. Pat. Nos. 4,768,292, 5,141,671, 5,150,006, 5,151,629, 5,294,870, 5,405,709, 5,484,922, 5,593,788, 5,645,948, 5,683,823, 5,755,999, 5,928,802, 5,935,720, 5,935,721, and 6,020,078.

Metal complexes of 8-hydroxyquinoline and similar derivatives (Formula E) constitute one class of useful host materials capable of supporting electroluminescence, and are particularly suitable for light emission of wavelengths longer than 500 nm, e.g., green, yellow, orange, and red 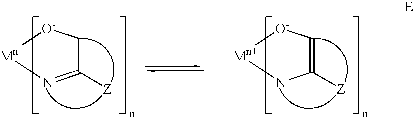
wherein:

M represents a metal;

n is an integer of from 1 to 3; and

Z independently in each occurrence represents the atoms completing a nucleus having at least two fused aromatic rings.

From the foregoing it is apparent that the metal can be a monovalent, divalent, or trivalent metal. The metal can, for example, be an alkali metal, such as lithium, sodium, or potassium; an alkaline earth metal, such as magnesium or calcium; or an earth metal, such as boron or aluminum. Generally any monovalent, divalent, or trivalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is typically maintained at 18 or less.

Illustrative of useful chelated oxinoid compounds are the following:

CO-1: Aluminum trisoxine [alias, tris(8-quinolinolato)aluminum(III)];

CO-2: Magnesium bisoxine [alias, bis(8-quinolinolato)magnesium(II)];

CO-3: Bis[benzo{f}-8-quinolinolato]zinc (II);

CO-4: Bis(2-methyl-8-quinolinolato)aluminum(III)-μ-oxo-bis(2-methyl-8-quinolinolato) aluminum(III);

CO-5: Indium trisoxine [alias, tris(8-quinolinolato)indium];

CO-6: Aluminum tris(5-methyloxine) [alias, tris(5-methyl-8-quinolinolato) aluminum(III)];

CO-7: Lithium oxine [alias, (8-quinolinolato)lithium(I)];

CO-8: Gallium oxine [alias, tris(8-quinolinolato)gallium(III)]; and

CO-9: Zirconium oxine [alias, tetra(8-quinolinolato)zirconium(IV)].

The host material in light-emitting layer 50 can be an anthracene derivative having hydrocarbon or substituted hydrocarbon substituents at the 9 and 10 positions, as described above for light-emitting layer 45. Benzazole derivatives (Formula G) constitute another class of useful host materials capable of supporting electroluminescence, and are particularly suitable for light emission of wavelengths longer than 400 nm, e.g., blue, green, yellow, orange or red 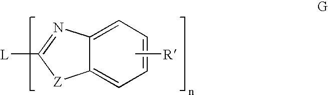
wherein:

n is an integer of 3 to 8;

Z is O, NR or S;

R′ is hydrogen; alkyl of from 1 to 24 carbon atoms, for example, propyl, t-butyl, heptyl, and the like; aryl or heteroatom substituted aryl of from 5 to 20 carbon atoms for example phenyl and naphthyl, furyl, thienyl, pyridyl, quinolinyl and other heterocyclic systems; or halo such as chloro, fluoro; or atoms necessary to complete a fused aromatic ring; and

L is a linkage unit consisting of alkyl, aryl, substituted alkyl, or substituted aryl, which conjugately or unconjugately connects the multiple benzazoles together.

An example of a useful benzazole is 2, 2′, 2″-(1,3,5-phenylene)-tris[1-phenyl-1H-benzimidazole].

Desirable fluorescent dopants include perylene or derivatives of perylene, derivatives of anthracene, tetracene, xanthene, rubrene, coumarin, rhodamine, quinacridone, dicyanomethylenepyran compounds, thiopyran compounds, polymethine compounds, pyrilium and thiapyrilium compounds, derivatives of distryrylbenzene or distyrylbiphenyl, bis(azinyl)methane boron complex compounds, and carbostyryl compounds. Illustrative examples of useful dopants include, but are not limited to, the following:

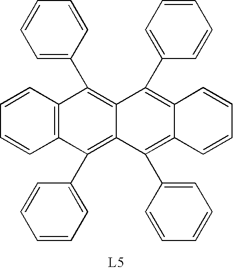

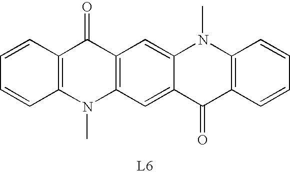

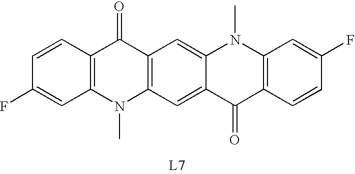

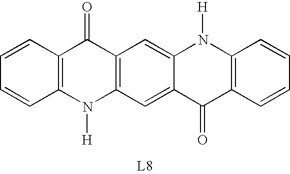

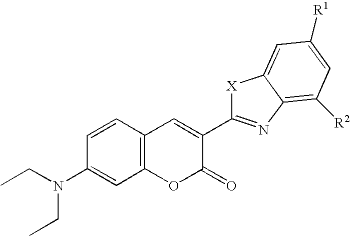

| | X | R1 | R2 |
|---|---|---|---|
| L9 | O | H | H |
| L10 | O | H | Methyl |
| L11 | O | Methyl | H |
| L12 | O | Methyl | Methyl |
| L13 | O | H | t-butyl |
| L14 | O | t-butyl | H |
| L15 | O | t-butyl | t-butyl |
| L16 | S | H | H |
| L17 | S | H | Methyl |
| L18 | S | Methyl | H |
| L19 | S | Methyl | Methyl |
| L20 | S | H | t-butyl |
| L21 | S | t-butyl | H |
| L22 | S | t-butyl | t-butyl |

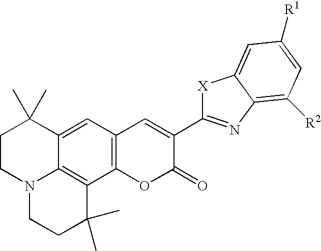

| | X | R1 | R2 |
|---|---|---|---|
| L23 | O | H | H |
| L24 | O | H | Methyl |
| L25 | O | Methyl | H |
| L26 | O | Methyl | Methyl |
| L27 | O | H | t-butyl |
| L28 | O | t-butyl | H |
| L29 | O | t-butyl | t-butyl |
| L30 | S | H | H |
| L31 | S | H | Methyl |
| L32 | S | Methyl | H |
| L33 | S | Methyl | Methyl |
| L34 | S | H | t-butyl |
| L35 | S | t-butyl | H |
| L36 | S | t-butyl | t-butyl |

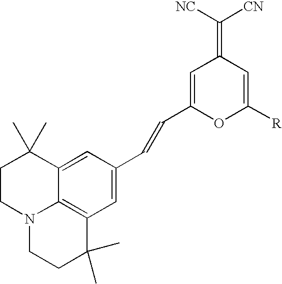

| | R |
|---|---|
| L37 | phenyl |
| L38 | methyl |
| L39 | t-butyl |
| L40 | mesityl |

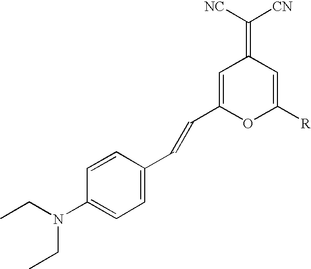

| | R |
|---|---|
| L41 | phenyl |
| L42 | methyl |
| L43 | t-butyl |
| L44 | mesityl |

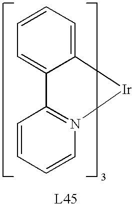

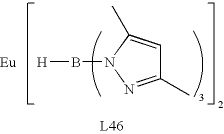

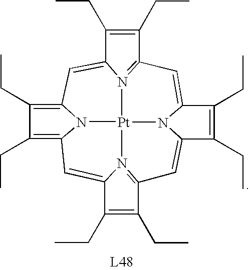

Other organic emissive materials can be polymeric substances, e.g. polyphenylenevinylene derivatives, dialkoxy-polyphenyienevinylenes, poly-para-phenylene derivatives, and polyfluorene derivatives, as taught by Wolk, et al. in commonly assigned U.S. Pat. No. 6,194,119 and references cited therein.

Certain yellow, orange, and red emissive materials can be particularly useful for this invention. A light-emitting yellow dopant can include a compound of the following structures: 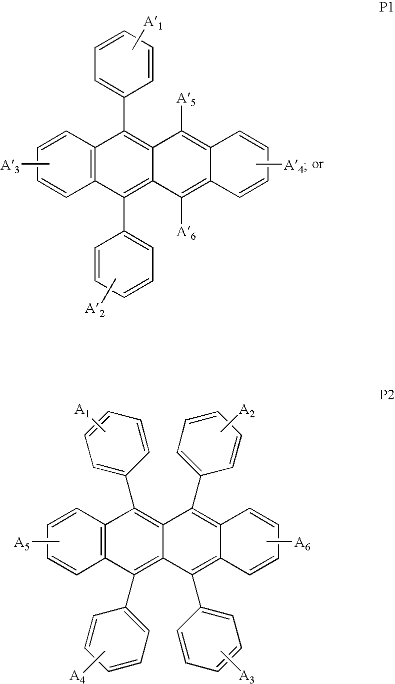
wherein A₁-A₆ represent one or more substituents on each ring and where each substituent is individually selected from one of the following:

Category 1: hydrogen, or alkyl of from 1 to 24 carbon atoms;

Category 2: aryl or substituted aryl of from 5 to 20 carbon atoms;

Category 3: hydrocarbon containing 4 to 24 carbon atoms, completing a fused aromatic ring or ring system;

Category 4: heteroaryl or substituted heteroaryl of from 5 to 24 carbon atoms such as thiazolyl, furyl, thienyl, pyridyl, quinolinyl or other heterocyclic systems, which are bonded via a single bond, or complete a fused heteroaromatic ring system;

Category 5: alkoxylamino, alkylamino, or arylamino of from 1 to 24 carbon atoms; or

Category 6: fluoro, or cyano.

Examples of particularly useful yellow dopants include 5,6,11,12-tetraphenylnaphthacene (P-3); 6,11-diphenyl-5,12-bis(4-(6-methyl-benzothiazol-2-yl)phenyl)naphthacene (P-4) and 5,6,11,12-tetra(2-naphthyl)naphthacene (P-5), the formulas of which are shown below:

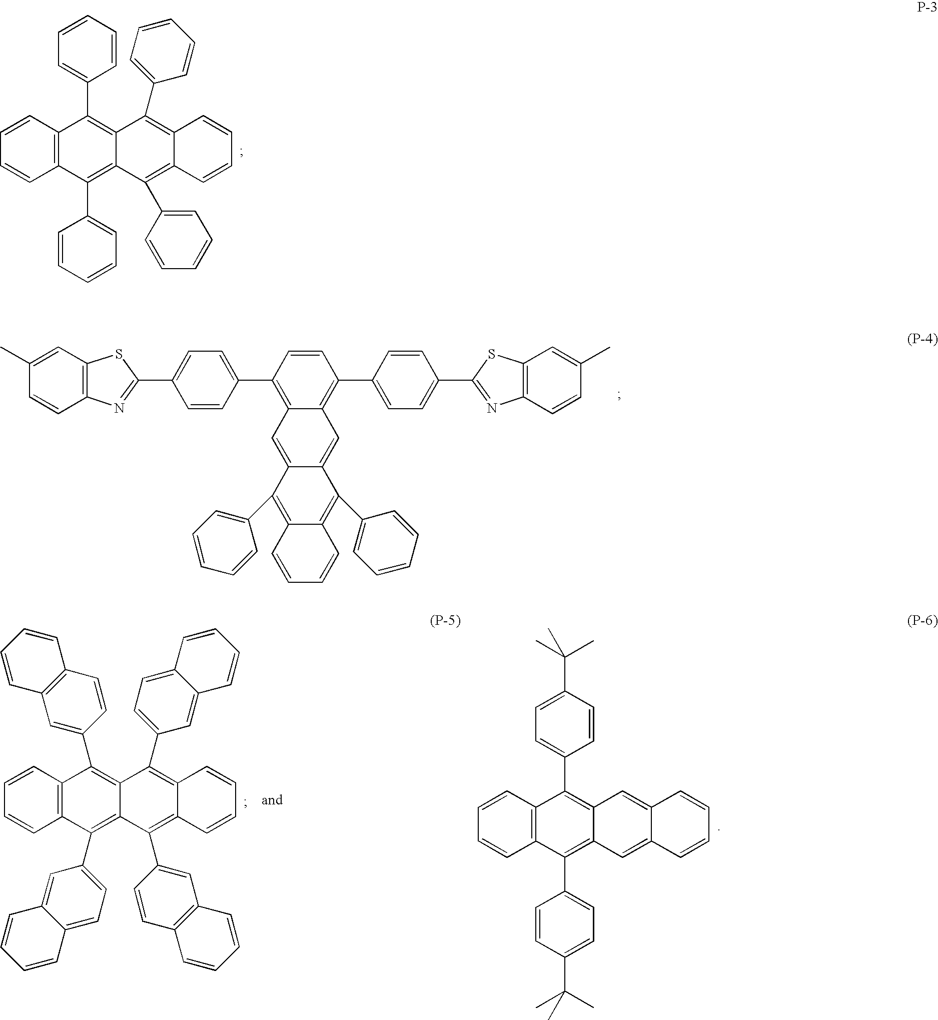

The yellow dopant can also be a mixture of compounds that would also be yellow dopants individually.

A light-emitting red dopant can include a diindenoperylene compound of the following structure: 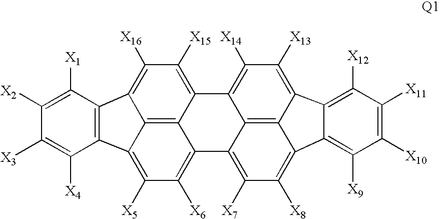
wherein X₁-X₁₆ are independently selected as hydro or substituents that provide red luminescence.

Illustrative examples of useful red dopants of this class include the following:

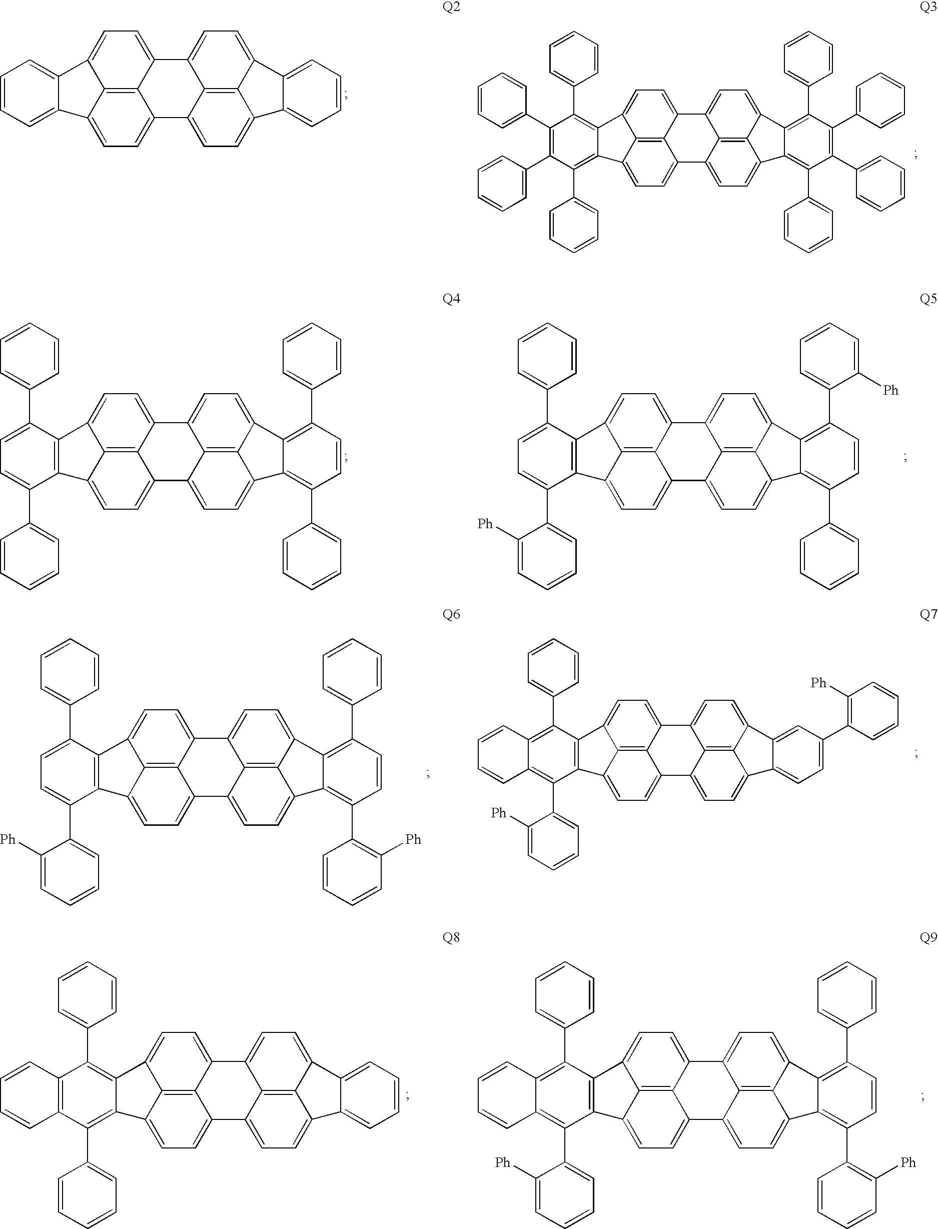

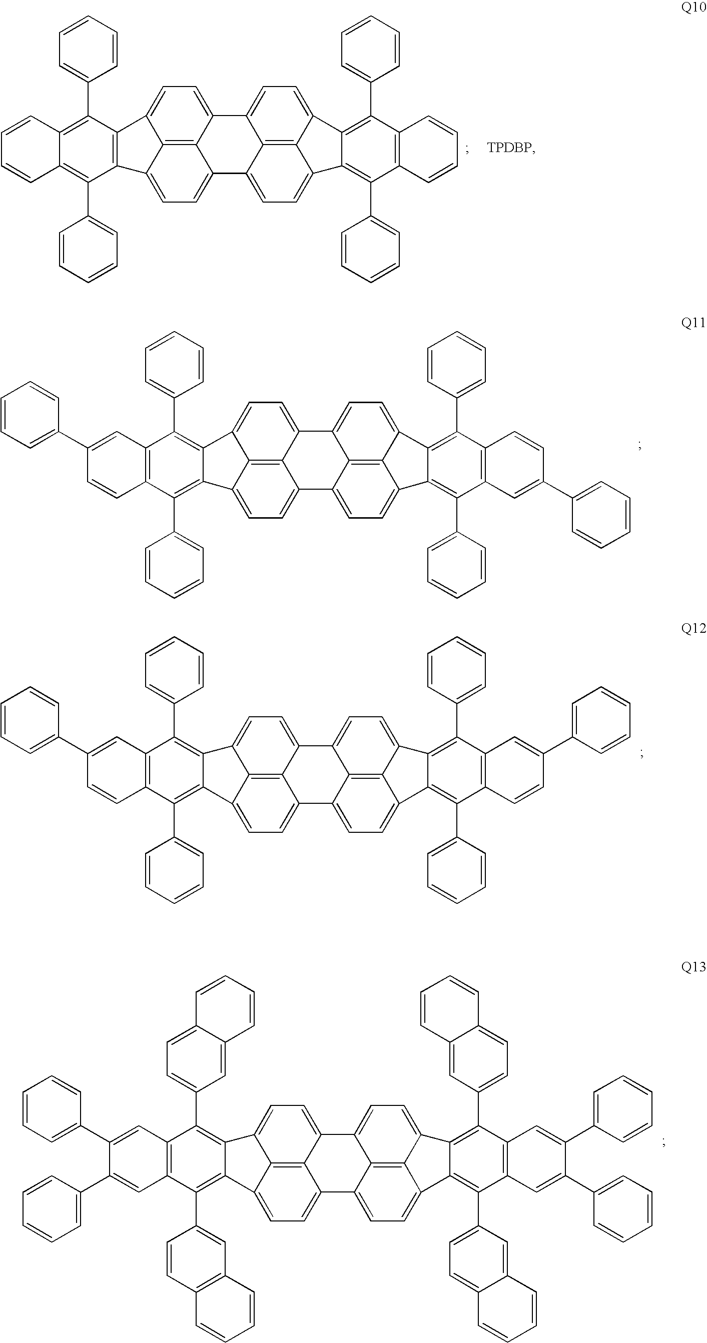

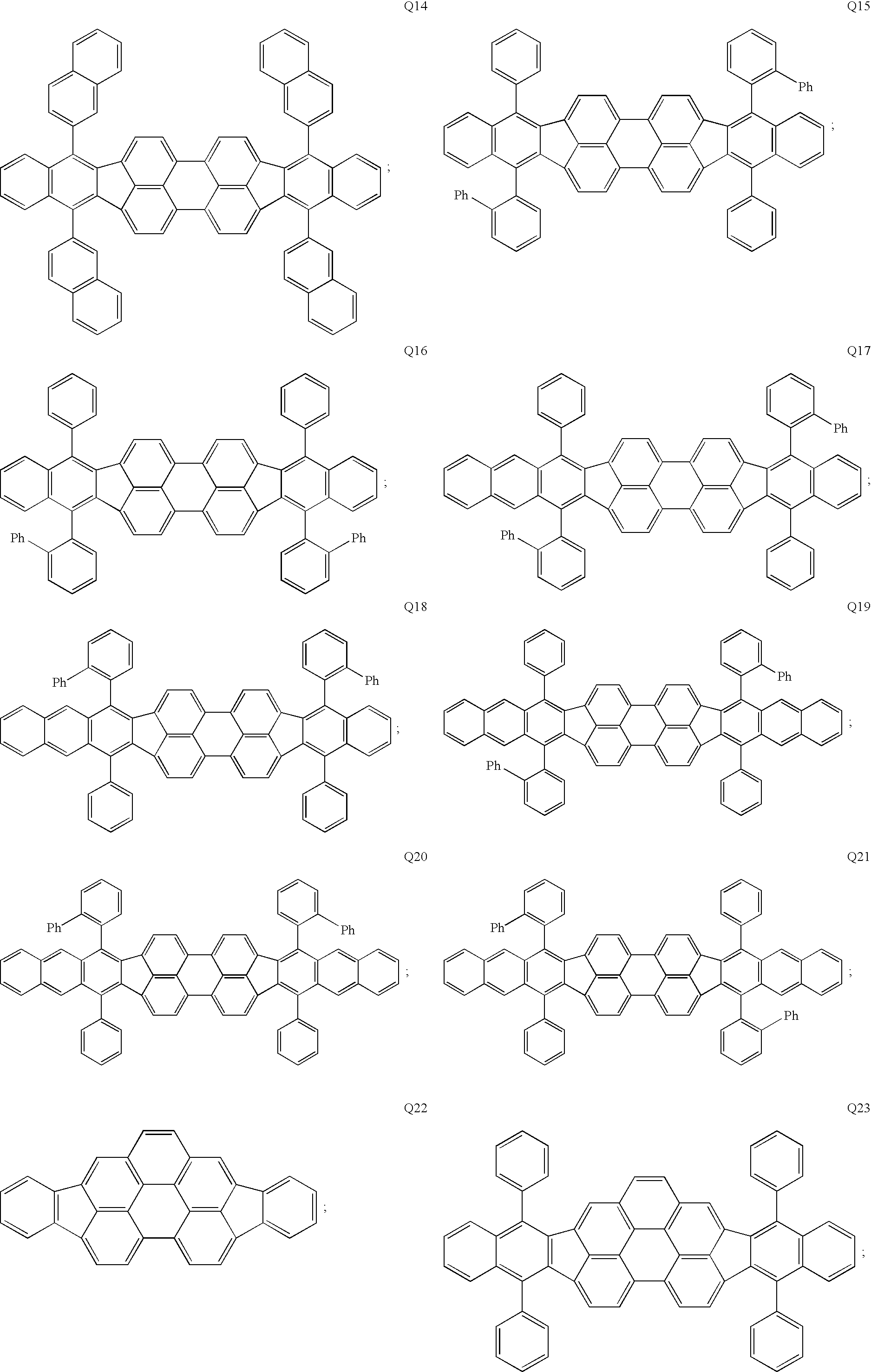

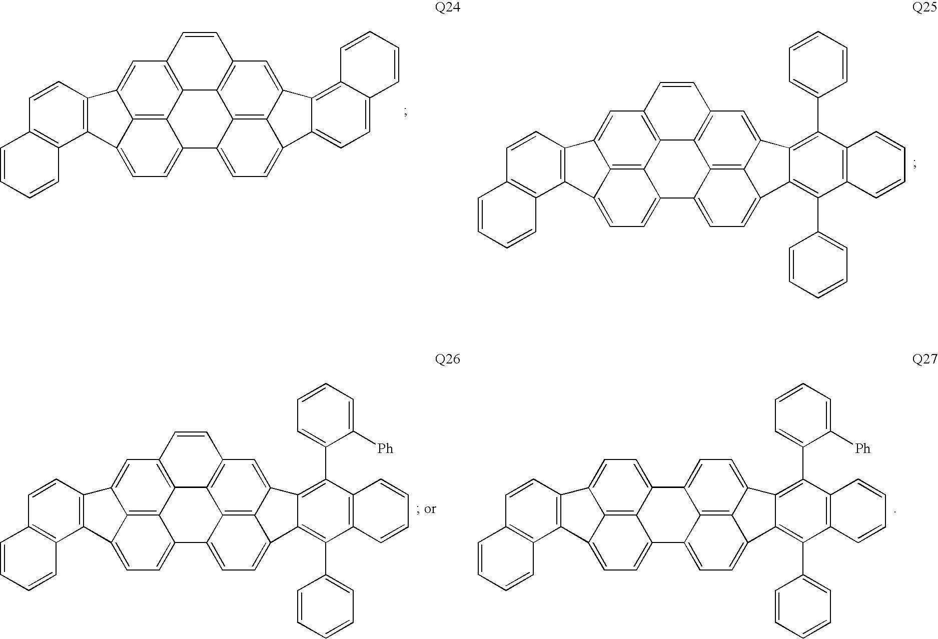

A particularly preferred diindenoperylene dopant is dibenzo {f,f′]-4,4′7,7′-tetraphenyl]diindeno-[1,2,3-cd:1′,2′,3′-lm]perylene (TPDBP, Q10 above).

Other red dopants useful in the present invention belong to the DCM class of dyes represented by: 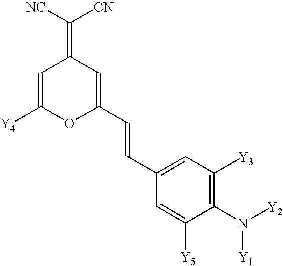
wherein:

Y₁-Y₅ represent one or more groups independently selected from hydro, alkyl, substituted alkyl, aryl, or substituted aryl; and

Y₁-Y₅ independently include acyclic groups or are joined pairwise to form one or more fused rings, provided that Y₃ and Y₅ do not together form a fused ring.

In a useful and convenient embodiment that provides red luminescence, Y₁-Y₅ are selected independently from: hydro, alkyl and aryl. Structures of particularly useful dopants of the DCM class are shown below:

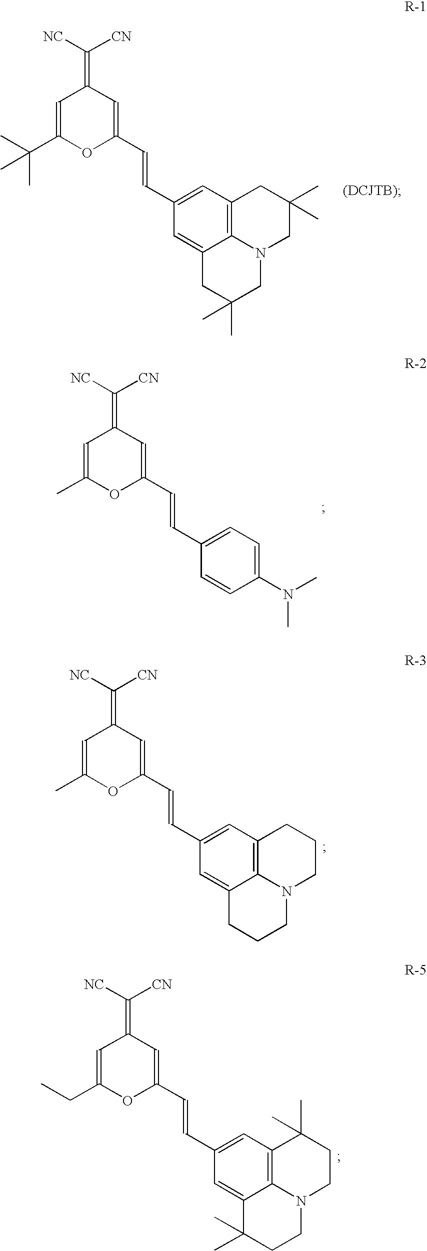

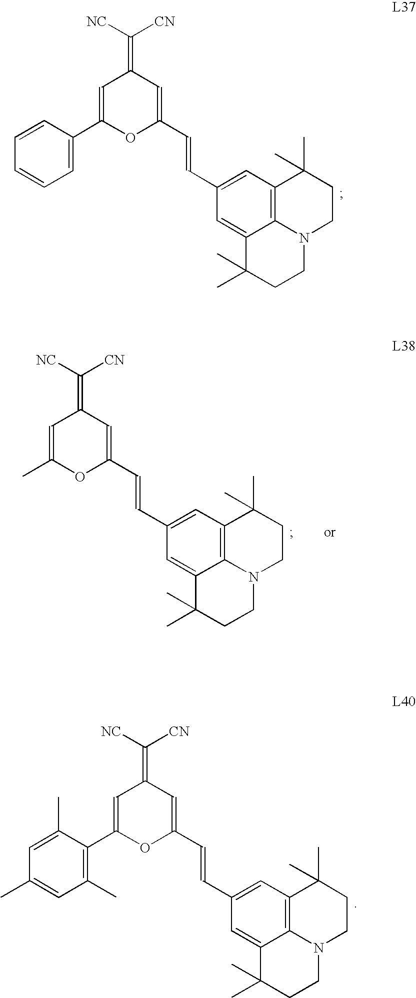

A preferred DCM-class dopant is DCJTB, R-1. The red dopant can also be a mixture of compounds that would also be red dopants individually. Further, the yellow-, orange-, or red-light-emitting layer 50 can include a mixture of red-emitting and yellow-emitting dopants.

While not always necessary, it is often useful that OLED device 10 includes an electron-transporting layer 55 disposed over light-emitting layer 50. Desired electron-transporting materials can be deposited by any suitable way such as evaporation, sputtering, chemical vapor deposition, electrochemical means, thermal transfer, or laser thermal transfer from a donor material. Preferred electron-transporting materials for use in electron-transporting layer 55 are metal chelated oxinoid compounds, including chelates of oxine itself (also commonly referred to as 8-quinolinol or 8-hydroxyquinoline). Such compounds help to inject and transport electrons and exhibit both high levels of performance and are readily fabricated in the form of thin films. Exemplary of contemplated oxinoid compounds are those satisfying structural Formula E, previously described.

Other electron-transporting materials include various butadiene derivatives as disclosed in U.S. Pat. No. 4,356,429 and various heterocyclic optical brighteners as described in U.S. Pat. No. 4,539,507. Benzazoles satisfying structural Formula G are also useful electron-transporting materials.

Other electron-transporting materials can be polymeric substances, e.g. polyphenylenevinylene derivatives, poly-para-phenylene derivatives, polyfluorene derivatives, polythiophenes, polyacetylenes, and other conductive polymeric organic materials such as those listed in Handbook of Conductive Molecules and Polymers, Vols. 1-4, H. S. Nalwa, ed., John Wiley and Sons, Chichester (1997).

It will be understood that, as is common in the art, some of the layers can have more than one function. For example, light-emitting layers 45 and 50 can have hole-transporting properties or electron-transporting properties as desired for performance of the OLED device. Hole-transporting layer 40 or electron-transporting layer 55, or both, can also have emitting properties. In such a case, fewer layers than described above can be sufficient for the desired emissive properties.

The organic EL media materials mentioned above are suitably deposited through a vapor-phase method such as sublimation, but can be deposited from a fluid, for example, from a solvent with an optional binder to improve film formation. If the material is a polymer, solvent deposition is useful but other methods can be used, such as sputtering or thermal transfer from a donor sheet. The material to be deposited by sublimation can be vaporized from a sublimator “boat” often includes a tantalum material, e.g., as described in U.S. Pat. No. 6,237,529, or can be first coated onto a donor sheet and then sublimed in closer proximity to the substrate. Layers with a mixture of materials can use separate sublimator boats or the materials can be pre-mixed and coated from a single boat or donor sheet.

An electron-injecting layer 60 can also be present between the cathode and the electron-transporting layer. Examples of electron-injecting materials include alkaline or alkaline earth metals, alkali halide salts, such as LiF mentioned above, or alkaline or alkaline earth metal doped organic layers.

The color filter 25 includes color filter elements for the color to be emitted from the pixel of OLED device 10 and is part of a color filter array that is disposed over organic EL element 70. Color filter 25 is constructed to have a bandpass spectrum to pass a preselected color of light in response to white light, so as to produce a preselected color output. A combination particularly useful in a full color OLED device is a color filter array including at least three separate color filters 25 that have bandpass spectra from 605 nm to 700 nm, from 495 nm to 555 nm, and from 435 nm to 480 nm, for passing red, green, and blue light, respectively. Several types of color filters are known in the art. One type of color filter 25 is formed on a second transparent substrate and then aligned with the pixels of the first substrate 20. An alternative type of color filter 25 is formed directly over the elements of OLED device 10. In a display comprising multiple pixels, the space between the individual color filter elements can also be filled with a black matrix (not shown) to reduce pixel cross talk and improve the display's contrast. While color filter 25 is shown here as being located between anode 30 and substrate 20, it can alternatively be located on the outside surface of substrate 20. For a top-emitting device, color filter 25 can be located over cathode 90.

OLED device 10 can also be constructed as a microcavity structure, wherein a reflective layer and a semi-reflective layer (which can be anode 30 and cathode 90) provide internal reflection of the emitted light and an enhancement of particular wavelengths of light. A microcavity structure for OLED devices has been described e.g. by Boroson, et al. in commonly assigned U.S. patent application Ser. No. 10/819,697 filed Apr. 7, 2004, entitled “Color OLED With Added Color Gamut Pixels”, the disclosure of which is herein incorporated by reference.

There are numerous configurations of the organic EL media layers wherein the present invention can be successfully practiced. Examples of organic EL media layers that produce white light are described, for example, in EP 1 187 235, EP 1 182 244, U.S. Patent Application Publication 2002/0025419 A1, U.S. Pat. Nos. 5,683,823, 5,503,910, 5,405,709, and 5,283,182. As shown in EP 1 187 235, a white light-emitting organic EL element with a substantially continuous spectrum in the visible region of the spectrum can be achieved by providing at least two different dopants for collectively emitting white light, e.g. by the inclusion of the following layers:

a hole-injecting layer 35 disposed over the anode;

a hole-transporting layer 40 that is disposed over the hole-injecting layer 35 and is doped with a light-emitting yellow dopant for emitting light in the yellow region of the spectrum;

a blue light-emitting layer 45 including a host material and a light-emitting blue dopant disposed over the hole-transporting layer 40; and

an electron-transporting layer 55.

Because such an emitter produces a wide range of wavelengths, it can also be known as a broadband emitter and the resulting emitted light known as broadband light.

The invention and its advantages can be better appreciated by the following comparative examples.

### EXAMPLE 1 (COMPARATIVE)

A comparative OLED device was constructed in the following manner:

1. A clean glass substrate was vacuum-deposited with indium tin oxide (ITO) to form a transparent electrode of 85 nm thickness;

2. The above-prepared ITO surface was treated with a plasma oxygen etch, followed by plasma deposition of a 0.1 nm layer of a fluorocarbon polymer (CFx) as described in U.S. Pat. No. 6,208,075;

3. The above-prepared substrate was further treated by vacuum-depositing a 160 nm layer of 4,4′-bis[N-(1-naphthyl)-N-phenylamino]biphenyl (NPB) as a hole-transporting layer (HTL);

4. A coating of 40 nm of 9-(2-naphthyl)-10-(4-biphenyl)anthracene (A-1) as a host and 0.6 nm of C-7 (compound above) as a blue dopant was evaporatively deposited on the above substrate to form a blue-light-emitting layer (blue EML);

5. A 10 nm electron-transporting layer (ETL) of tris(8-quinolinolato)aluminum (III) (ALQ) was vacuum-deposited onto the substrate at a coating station that included a heated graphite boat source; and

6. A 1.0 nm layer of lithium fluoride was evaporatively deposited onto the substrate, followed by a 100 nm layer of aluminum, to form a cathode layer.

### EXAMPLES 2 TO 5 (INVENTIVE)

An OLED device was constructed in the manner described in Example 1, except that step 4 in each case was as follows:

4. A coating of 40 nm of a mixture of 9-(2-naphthyl)-10-(4-biphenyl)anthracene (A-1) and 2-tert-butyl-9,10-bis(2-naphthyl)anthracene (B-9), in the relative percentages by volume shown in Table 1 below, as a host and 0.6 nm of C-7, as a blue dopant was evaporatively deposited on the above substrate to form a blue-light-emitting layer (blue EML).

### EXAMPLE 6 (COMPARATIVE)

An OLED device was constructed in the manner described in Example 1, except that step 4 was as follows:

4. A coating of 40 nm of 2-tert-butyl-9,10-bis(2-naphthyl)anthracene (B-9) as a host and 0.6 nm of C-7, as a blue dopant was evaporatively deposited on the above substrate to form a blue-light-emitting layer (blue EML).

### RESULTS (EXAMPLES 1-6)

The luminance loss was measured by subjecting the cells to a constant current density of 80 mA/cm² at RT (room temperature). The devices were also examined visually, both unaided and microscopically, for crystallization. The following table shows the results.

TABLE 1

| | | | | Relative | |
|---|---|---|---|---|---|
| | | | | Hours to | |
| | | | | 50% | |
| | | | | luminance | |
| | | | % | @80 | |
| Example | Type | % BNA | TBADN | mA/cm² | Crystallization |
| 1 | Com- | 100% | — | 1.00 | Yes |
| | parative | | | | |
| 2 | Inventive | 75% | 25% | 0.93 | None |
| 3 | Inventive | 50% | 50% | 0.82 | None |
| 4 | Inventive | 25% | 75% | 0.84 | None |
| 5 | Inventive | 10% | 90% | 0.87 | None |
| 6 | Com- | — | 100% | 0.62 | None |
| | parative | | | | |

This data shows that the use of 9-(2-naphthyl)-10-(4-biphenyl)anthracene (A-1) as the sole host material in the blue-emitting layer gives excellent lifetime, but causes crystallization in the emitting layer under certain process conditions (Example 1). The use of 2-tert-butyl-9,10-bis(2-naphthyl)anthracene (B-9) as the host material limits the crystallization problem, of the device is greatly reduced. However, a mixture of A-1 and B-9 gives the device lifetime that is nearly that when using pure A-1, but does not show the crystallization problem. Thus, a blue-light-emitting layer for an OLED device can be prepared as described herein with excellent stability without problems of crystallization.

The invention has been described in detail with particular reference to certain preferred embodiments thereof, but it will be understood that variations and modifications can be effected within the spirit and scope of the invention.

### PARTS LIST

10 OLED device
20 substrate
25 color filter
30 anode
35 hole-injecting layer
40 hole-transporting layer
45 light-emitting layer
50 light-emitting layer
55 electron-transporting layer
60 electron-injecting layer
70 organic EL element
90 cathode

1. In an OLED device having at least one light-emitting layer, the improvement comprising:
a) at least first and second different host materials, wherein the first host material includes an anthracene derivative that can crystallize and the second host material includes a second anthracene derivative which does not crystallize, wherein the stability of the first host material is greater than the stability of the second host material, and the mixed first and second host materials reduce the crystallization effects of the first host material, and the stability of the mixed first and second host materials is improved relative to the stability of the second host material; and
b) a light-emitting material.

2. The OLED device of claim 1 having at least one light-emitting layer, the improvement comprising:
a) the first host material includes a monoanthracene derivative of 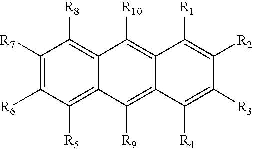
wherein:
R₁-R₈ are H;
R₉ is not the same as R₁₀;
R₉ is a naphthyl group having no fused rings with aliphatic carbon ring members;
R₁₀ is a biphenyl group having no fused rings with aliphatic carbon ring members;
provided that R₉ and R₁₀ are free of amines and sulfur compounds; and
b) the second host material is an anthracene derivative selected so that the stability of the first host material is greater than the stability of the second host material, and the mixed first and second host materials reduce the crystallization effects of the first host material, and the stability of the mixed first and second host materials is improved relative to the stability of the second host material.

3. The OLED device of claim 2 wherein the first host material is

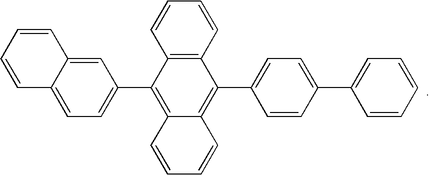

4. The OLED device of claim 2 wherein the second host material has the formula 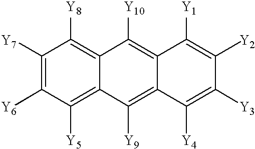
wherein:
Y₁-Y₈ are independently H, an alkyl group, an alkoxy group, or an alkenyl group, and at least one of Y₁-Y₈ is not H; and
Y₉ and Y₁₀ are aromatic groups and Y₉ is the same as Y₁₀.

5. The OLED device of claim 4 wherein Y₉ and Y₁₀ are selected from the group consisting of phenyl, tolyl, biphenyl, naphthyl, terphenyl, fluoranthenyl, fluorenyl, pyrenyl, or phenanthryl, pyridinyl and quinolinyl.

6. The OLED device of claim 2 wherein the second host material is

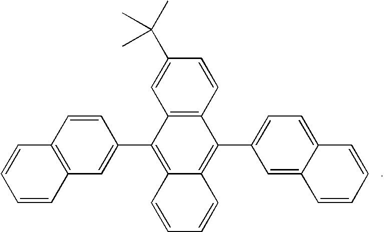

7. The OLED device of claim 2 wherein the first host material is in a range of from 10-90 percent by volume of the mixture of the first and second host materials.

8. The OLED device of claim 2 wherein the light-emitting layer includes a bis(azinyl)azene boron complex compound.

9. The OLED device of claim 8 wherein the bis(azinyl)azene boron complex compound has the following structure 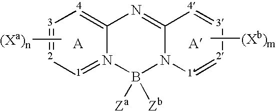
wherein:
A and A′ represent independent azine ring systems corresponding to 6-membered aromatic ring systems containing at least one nitrogen;
(X^{a})ₙ and (X^{b})ₘ represent one or more independently selected substituents and include acyclic substituents or are joined to form a ring fused to A or A′;
m and n are independently 0 to 4;
Z^{a} and Z^{b} are independently selected substituents;
1, 2, 3, 4, 1′, 2′, 3′, and 4′ are independently selected as either carbon or nitrogen atoms; and
provided that X^{a}, X^{b}, Z^{a}, and Z^{b}, 1, 2, 3, 4, 1′, 2′, 3′, and 4′ are selected to provide blue luminescence.

10. The OLED device of claim 9 wherein the bis(azinyl)azene boron complex compound is [chemical structure]
